(19) United States
(12) Patent Application Publication
(10) Pub. No.: US 2006/0227515 A1
(43) Pub. Date: Oct. 12, 2006

(54) Cooling apparatus for electronic device

(75) Inventors: Takafumi Enami, Hadano (JP); Akio Idei, Hadano (JP); Shigemasa Sato, Hadano (JP); Chikakazu Ninomiya, Kaisei (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 11/368,055

(22) Filed: Mar. 2, 2006

(30) Foreign Application Priority Data
Mar. 4, 2005 (JP) 2005-059852

(51) Int. Cl. H05K 7/20

(52) U.S. Cl. 361/720; 361/702

(57) ABSTRACT

A cooling apparatus for cooling a plurality of electronic devices each having a large heating value and a small area, capable of effectively cooling the semiconductor chips with the use of a single cooler, comprises a plurality of thermal conductors mounted on the electronic devices and formed with thermal conductive fins, a housing formed with fins fitted with the fins of the thermal conductors, and a cooling device mounted on the housing, for removing heat from the electronic devices, wherein the housing is formed therein with a plane heat-pipe.

### INCORPORATION BY REFERENCE

The present application claims priority from Japanese application JP 2005-059852 filed on Mar. 4, 2005, the content of which is hereby incorporated by reference into this application.

### FIELD OF THE INVENTION

The present invention relates to a cooling. apparatus for removing heat generated from an electronic device such as a semiconductor chip or an integrated circuit chip.

### DESCRIPTION OF THE RELATED ART

There has been increased demands for speeding up a process in an electronic computer, and accordingly, these years, circuit chips in which semiconductor devices are integrated in a large scale have been developed. Further, in order to shorten electric wirings connecting among these integrated circuit chips as possible as it can, there have been developed methods for mounting a plurality of integrated circuit chips in a micro-package.

Conventionally, in particular, with respect to a large scale electronic computer, a cooling apparatus for semiconductor chips, having an excellent cooling function and having a flexible structure capable of vertically and horizontally absorbing assembly errors and thermal deformation has been known as disclosed in JP-A-60-126853. The publication discloses a configuration in which a thermal conductor mounted on a semiconductor chip and having a fin-like shape is fitted with a housing similarly having a fin-like shape in order to conduct a heat from the semiconductor chip to a cooling component such as radiation fins or a water cooling jacket connected to the housing, through the thermal conductor and the housing. Further, the housing has been made of a material having a high thermal conductivity, such as copper or aluminum.

The greater the heating value of the semiconductor chip is, the larger the area of the cooling component is, and thus, it is resulted that the area of the housing connected to the cooling component is increased. In this case, in order to allow the cooling component to effectively exhibit its cooling function, the heat transmitted from the semiconductor chip to the cooling component through the thermal conductor should be widely distributed in the housing in order to conduct the heat between the housing and the cooling component, uniformly over a connecting surface therebetween. On the contrary, should the micro-package be small-sized, the density of heat conducted to the housing would be further increased, resulting in insufficient heat distribution in the housing made of a conventionally used material such as copper or aluminum, and the heat is conducted with a convexity pattern between contact surfaces of the housing and the cooling component, that is, the heat conduction is largest at its center part but is decreased toward its periphery, and accordingly, there has been caused such a disadvantage that the heat conduction is locally deteriorated, and the cooling component connected to the housing cannot satisfactorily exhibit its function.

In order to solve the above-mentioned problems, there has been proposed such a manner that the thickness of the housing is increased so as to widely distribute the heat in the housing. However, this method has caused a disadvantage that the external dimensions and weight of the electronic device are increased due to great increase in the thickness of the housing.

### BRIEF SUMMARY OF THE INVENTION

The present invention is devised in order to solve a problem of insufficient thermal diffusion in the housing, and accordingly, one object of the present invention is to provide a cooling apparatus for an electronic device, which can sufficiently diffuse heat in the housing in order to effectively cool a plurality of semiconductor chips having high heating values and small areas, with the use of only a single cooler.

According to the present invention, there is provided a cooling device for cooling electronic devices, comprising a plurality of thermal conductors mounted on electronic devices and formed with heat transfer fins, a housing formed with fins fitted with the fines of the thermal conductors, a cooling means mounted on the housing, for removing heat from the electronic devices, characterized in that a plane heat pipe is formed in the housing.

With the configuration according to the present invention, the heat may be sufficiently diffused in the housing, and accordingly, the heat is conducted with a uniform heat flux at a surface made into contact with a cooling component, thereby enhancing the performance of the cooling apparatus as well as making the housing thin and light-weight.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWINGS

FIG. 1 is a sectional view illustrating an embodiment 1 of a cooling apparatus for an electronic device, according to the present invention;

FIG. 2 is a sectional view illustrating an embodiment 2 of a cooling apparatus for an electronic device, according to the present invention;

FIG. 3 is a sectional view illustrating an embodiment 3 of a cooling apparatus for an electronic device, according to the present invention;

FIG. 4 is a sectional view illustrating an embodiment 4 of a cooling apparatus for an electronic device, according to the present invention;

FIG. 5 is a sectional view illustrating an embodiment 5 of a cooling apparatus for an electronic device, according to the present invention; and

FIG. 6 is a partly sectioned perspective view illustrating the embodiment of the cooling apparatus shown in FIG. 1.

### DETAILED DESCRIPTION OF THE INVENTION

Explanation will be hereinbelow made of embodiments according to the present invention with reference to the accompanying drawings.

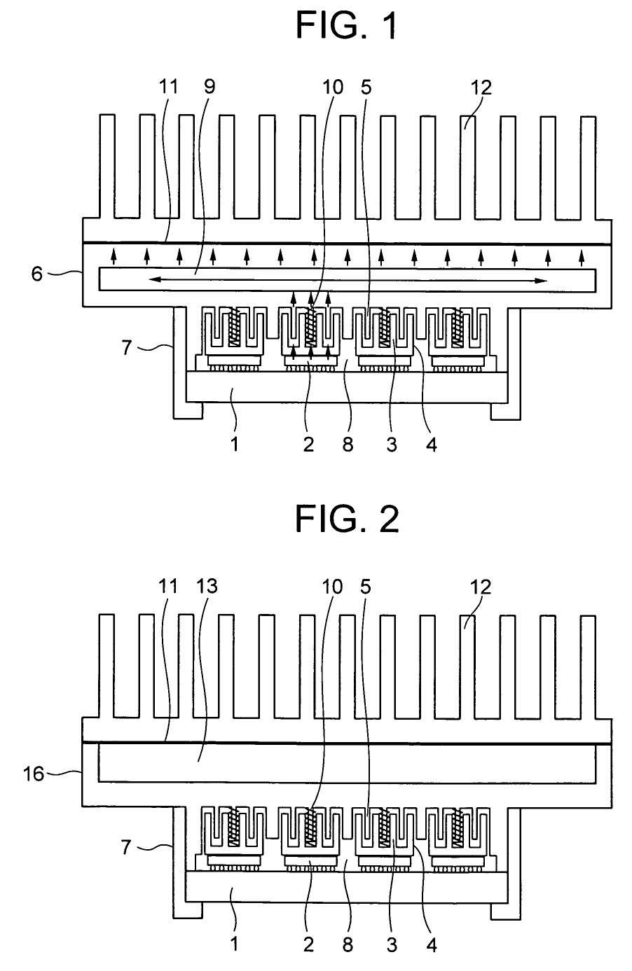

FIGS. 1 and 6 show an embodiment 1 of the present invention. FIG. 6 is a partly sectioned perspective view illustrating an embodiment 1 of the present invention while FIG. 1 is an enlarged sectional view illustrating several parts shown in FIG. 6. In the drawings, there is shown a circuit board 1 made of a ceramic material or an organic material, on which semiconductor chips 2 are mounted. On the semiconductor chips 2 are mounted respectively thermal conductors 4 formed with fins 3, and a housing 6 formed therein with fins 5 adapted to be fitted with the fins 3 of the thermal conductors 4 is mounted on the thermal conductors 4. The housing 6 is secured to the circuit board 1 through the intermediary of a frame 7, and a gas having a high thermal conductivity is filled in a space 8 surrounded by the housing 6, the frame 7 and the circuit board 1. Further, the housing 6 is formed therein with a plane heat pipe 9. The plane heat pipe 9 defines therein a closed space having inner walls with a capillary structure and including therein a small quantity of working liquid enclosed under a vacuum condition, and accordingly has such a function that heat applied to a part of the wall surfaces thereof is conducted in the closed space while the heat is uniformly diffused over the overall areas of the remaining wall surfaces of the closed space where no heat has been applied, by means of the working liquid therein. Coil springs 10 are located between the thermal conductors 4 and the housing 6 in order to make the thermal conductors 4 into close contact with the semiconductor chips 2. Heat sink 12 is mounted on the housing 6 through the intermediary of a thermal conductive medium 11 such as heat conductive grease, which is flexible.

Further, heat generated from the semiconductor chips 2 is conducted from the semiconductor chips 12 to the heat sink 12 as indicated by the arrows shown in FIG. 1. With the configuration as stated above, the heat generated from the semiconductor chips 2 is conducted to the thermal conductors 4, from which the heat is then conducted to the housing 6 by way of the fins 3 of the thermal conductor 4 and the fins 5 of the housing 6. In this case, since the heat flows only within the areas of the thermal conductors 4, the density of the heat is relatively high. Thus, the heat having transmitted into the housing 6 is uniformly diffused over the overall interior of the space by means of the plane heat pipe 9 formed in the housing 6, and accordingly, the heat uniformly flows over the overall surface of the housing 6 on the surface side made into close contact with the thermal conductive medium 11 while the density thereof becomes small. Thereafter, the heat is transmitted from the housing 6 to the heat sink 12 through the intermediary of the thermal conductive medium 11, and is then radiated into the air from the heat sink 12.

With the configuration of this embodiment, by the plane heat pipe 9 having a thermal diffusion function more than 100 times that of the material such as copper or aluminum used in the housing of the conventional cooling device, the heat conducted to the housing 6 through the thermal conductors 4 is rapidly diffused in the plane heat pipe 9, and thus, the heat is diffused so as to have a uniform density at a heat transfer area wherein the heat is transferred from the housing 6 to the heat sink 12 through the intermediary of the thermal conductive medium 11. Therefore, since the heat receiving surfaces of the heat sink 12 may be effectively utilized in its entirety, the performance of the heat sink 12 may be enhanced; thereby it is possible to enhance the performance of the cooling apparatus. Further, with the configuration of this embodiment, in which the plane heat pipe 9 has a very thin thickness of, for example, few millimeters, and further has therein a hollow space, the external height of the housing 10 may be decreased in comparison with a conventional housing made of cooper, aluminum or the like and having a performance the same as that of this embodiment, thereby it is possible to decrease the weight of the cooling apparatus.

FIG. 2 is a sectional view illustrating an embodiment 2 according to the present invention. In FIG. 2, a heat pipe 13 is embedded in a recess formed in an upper part of a housing 16. Contact surfaces of the housing 16 and the heat pipe 13 are formed by pressing them against each other, directly, or through the intermediary of a thermal conductive medium such as thermal conductive grease. Except that stated just above, the configuration of the embodiment 2 is the same as that shown in FIG. 1.

According to this embodiment, there may be exhibited technical effects and advantages the same as those obtained by the embodiment 1.

It is noted that the heat-pipe 13 may be composed of one or more of rod-like or plane heat-pipes which are embedded.

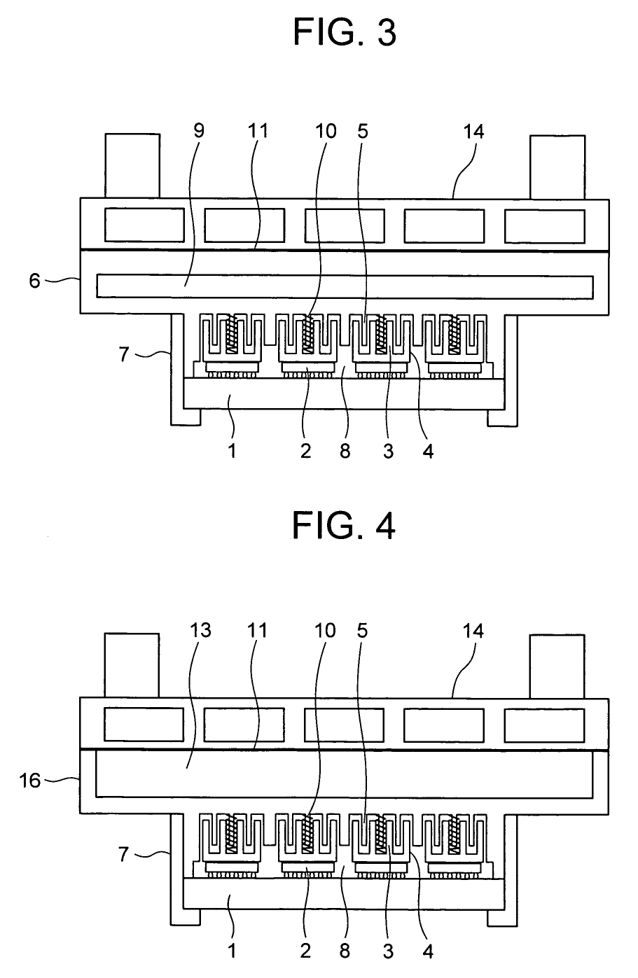

FIG. 3 is a sectional view illustrating an embodiment 3 according to the present invention. In FIG. 3, a cooling water jacket 14 is mounted on the housing 6 through the intermediary of a flexible thermal conductive medium 11 such as thermal conductive grease. Cooling water at a low temperature flows through the water cooling jacket 14. The configuration of the embodiment 3 is the same as that shown in FIG. 1, except that stated just above.

With the configuration stated above, the heat conducted to the plane heat pipe 9, similar to the plane heat pipe 9 shown in FIG. 1, is distributed in the housing 6 by means of the plane heat pipe 9, and then, the thus distributed heat is uniformly transmitted to the cooling water jacket 14 by way of the thermal conductive medium 11, and is radiated into the cooling water through the cooling water jacket 14.

According to this embodiment, the cooling water jacket 14 may radiate heat by a large heating value in comparison with the heat sink 12 in the embodiment 1, and accordingly, the performance of the cooling apparatus may be further enhanced.

FIG. 4 is a sectional view illustrating an embodiment 4 according to the present invention. In FIG. 4, a heat pipe 13 is embedded in the outer surface of a housing 16. A thermal conductive medium 8 such as grease may be interposed between contact surfaces of the housing 16 and the heat pipe 13. Alternatively, the surfaces of the housing 16 and the heat pipe 13 may be made into press-contact with each other. It is noted that the configuration of this embodiment is the same as that shown in FIG. 3, except that as stated just above.

According to this embodiment, there may be exhibited technical effects and advantages the same as those explained in the embodiment 3.

It is noted that the heat pipe 13 may be composed of one or more of rod-like heat pipes or plane heat pipes which are embedded.

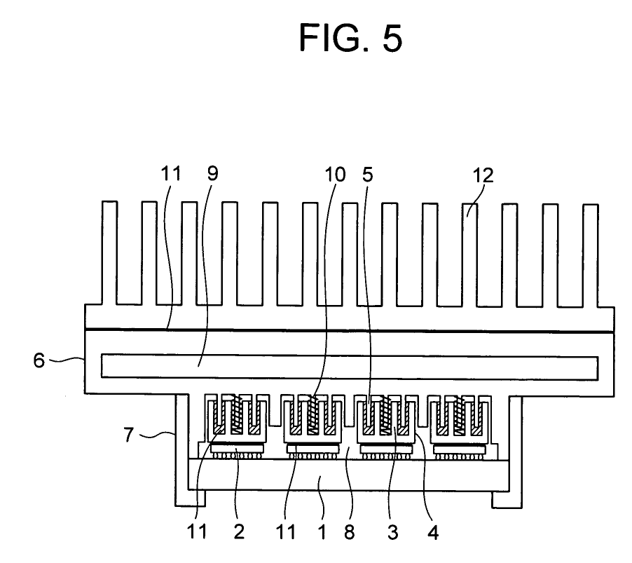

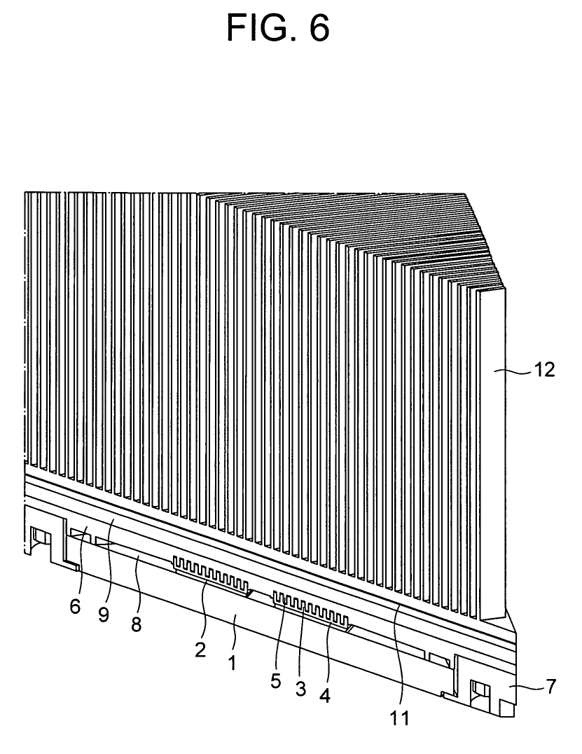

FIG. 5 is a sectional view illustrating an embodiment 5 according to the present invention. In FIG. 5, the configuration of this embodiment is the same as that shown in FIG. 1, except that a thermal conductive medium 11 such as thermal conductive grease is filled in fine gaps between the fitted parts of the fins 3 of the thermal conductor 4 and the fins 5 of the housing 6, and is also interposed between the contact surfaces of the semiconductor chip 2 and the thermal conductor 4.

According to this embodiment, the heat conductivity of the fine gaps between the fitted parts of the fins 3 of the thermal conductor 4 and the fins 5 of the housing 6 and between the contact surfaces of the semiconductor chip 2 and the thermal conductor 4 may be enhanced by the thermal conductive medium 11, thereby it is possible to further enhance the performance of the cooling apparatus.

It is noted that the explanation has been made of the embodiment 5, being based upon the configuration shown in FIG. 1 (the embodiment 1). Similar technical effects and advantages may be obtained although it may be applied in any of the embodiments 2, 3 and 4.

It should be further understood by those skilled in the art that although the foregoing description has been made on embodiments of the invention, the invention is not limited thereto and various changes and modifications may be made without departing from the spirit of the invention and the scope of the appended claims.

1. A cooling apparatus for cooling a plurality of electronic devices mounted on a circuit board, comprising a plurality of thermal conductors mounted on the electronic devices and formed with thermal conductive fins, a housing formed with fins fitted with the fins of the thermal conductors, and cooling means mounted on the housing for removing heat from the electronic devices, wherein a plane heat pipe is formed in the housing.

2. A cooling apparatus for cooling a plurality of electronic devices mounted on a circuit board, comprising a plurality of thermal conductors mounted on the electronic devices and formed with heat conductive fins, a housing having fins fitted with the fins of the thermal conductors, a heat pipe embedded in a recess in an upper part of the housing, and cooling means mounted on the heat pipe, for removing heat from the electronic devices.

3. A cooling apparatus as set forth in claim 1, wherein the cooling means for removing heat from the electronic devices is a heat sink or a water cooling jacket.

4. A cooling apparatus as set forth in claim 2, wherein the cooling means for removing heat from the electronic devices is a heat sink or a water cooling jacket.

5. A cooling apparatus as set forth in claim 1, wherein a heat conductive medium is interposed between the electronic devices and the thermal conductors and/or between the thermal conductive fins of the thermal conductors and the fins formed on the housing.

6. A cooling apparatus as set forth in claim 2, wherein a heat conductive medium is interposed between the electronic devices and the thermal conductors and/or between the thermal conductive fins of the thermal conductors and the fins formed on the housing.

7. A cooling apparatus as set forth in claim 3, wherein a heat conductive medium is interposed between the electronic devices and the thermal conductors and/or between the thermal conductive fins of the thermal conductors and the fins formed on the housing.

8. A cooling apparatus as set forth in claim 4, wherein a heat conductive medium is interposed between the electronic devices and the thermal conductors and/or between the thermal conductive fins of the thermal conductors and the fins formed on the housing.

9. A cooling apparatus as set forth in claim 2, wherein the heat pipe embedded in the recess in the upper part of the housing is a plane heat-pipe.
